(19) United States
(12) Patent Application Publication
(10) Pub. No.: US 2017/0102429 A1
(43) Pub. Date: Apr. 13, 2017

(54) TEST APPARATUS, TEST SIGNAL SUPPLY APPARATUS, TEST METHOD, AND COMPUTER READABLE MEDIUM

(71) Applicant: ADVANTEST CORPORATION, Tokyo (JP)

(72) Inventor: Koji TAKAHASHI, Saitama (JP)

(21) Appl. No.: 15/054,145

(22) Filed: Feb. 26, 2016

(30) Foreign Application Priority Data
Oct. 8, 2015 (JP) 2015-200330

(51) Int. Cl. G01R 31/3177; G01R 31/317

(52) U.S. Cl. CPC G01R 31/3177; G01R 31/31707

(57) ABSTRACT

To reduce test costs by reducing the number of pattern generators provided to a test apparatus. A test apparatus that tests a device under test and a test method are provided, the test apparatus comprising: a packet transmitting unit that packetizes and transmits, during a test of the device under test, a test pattern to be supplied to the device under test; a packet transferring unit that transfers a packet transmitted by the packet transmitting unit; a packet receiving unit that receives the test pattern transferred via the packet transferring unit; a buffering unit that buffers the test pattern received by the packet receiving unit; and a test signal supply unit that supplies the device under test with a test signal according to the test pattern acquired from the buffering unit.

The contents of the following Japanese patent application(s) are incorporated herein by reference:
NO. 2015-200330 filed on Oct. 8, 2015.

### BACKGROUND

1. Technical Field

The present invention relates to a test apparatus, a test signal supply apparatus, a test method and a computer readable recording medium.

2. Related Art

Conventionally, in a test apparatus to test a device under test, a pattern generator to generate test patterns is provided near the device under test, and the pattern generator generates a test pattern in response to a signal indicating a test start, and supplies it to the device under test (see, as related documents, Patent Documents 1 to 5 for example).

Patent Document 1: Japanese Patent Application Publication No. 2003-35753

Patent Document 2: Japanese Patent Application Publication No. H4-264931

Patent Document 3: Japanese Patent Application Publication No. 2004-144488

Patent Document 4: Japanese Patent Application Publication No. 2001-155497

Patent Document 5: Japanese Patent Application Publication No. H10-160808

Such a pattern generator has been realized by a dedicated design with hardware by using an ASIC and/or a FPGA, or the like in order to perform a test cycle for a device under test at a high speed. Accordingly, when a plurality of devices under test are measured with a single test apparatus, expensive pattern generators have to be provided near the plurality of devices under test, increasing costs of the test apparatus. Also, a change in a test pattern generator sometimes involves a change in hardware, and this necessitates a change in all of the plurality of pattern generating units, increasing labor and costs.

### SUMMARY

Therefore, it is an object of an aspect of the innovations herein to provide a test apparatus, a test signal supply apparatus, a test method, and a computer readable medium, which are capable of overcoming the above drawbacks accompanying the related art. The above and other objects can be achieved by combinations described in the claims. A first aspect of the present invention provides a test apparatus that tests a device under test and a test method, the test apparatus comprising:

a packet transmitting unit that packetizes and transmits, during a test of the device under test, a test pattern to be supplied to the device under test;

a packet transferring unit that transfers a packet transmitted by the packet transmitting unit;

a packet receiving unit that receives the test pattern transferred via the packet transferring unit;

a buffering unit that buffers the test pattern received by the packet receiving unit; and

a test signal supply unit that supplies the device under test with a test signal according to the test pattern acquired from the buffering unit.

A second aspect of the present invention provides a test signal supply apparatus provided in a test apparatus that tests a device under test, the test signal supply apparatus comprising:

a packet receiving unit that receives, from a packet transferring unit that transfers in a packet a test pattern to be supplied to the device under test, the test pattern during a test of the device under test;

a buffering unit that buffers the test pattern received by the packet receiving unit; and

a test signal supply unit that supplies the device under test with a test signal according to the test pattern acquired from the buffering unit.

A third aspect of the present invention provides a computer readable recording medium having recorded therein a program that, upon being executed by a computer, generates the test pattern to be used by the test apparatus according to the first aspect, wherein

the program causes the computer to function as:
a pattern generating unit that, during the test of the device under test, generates the test pattern to be supplied to the device under test; and
a packet transmitting unit that packetizes and transmits the generated test pattern.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration example of a test apparatus 100 according to the present embodiment together with a DUT 10.

FIG. 2 shows one example of an operation flow of the test apparatus 100 according to the present embodiment.

FIG. 3 shows a first variant of the test apparatus 100 according to the present embodiment together with the DUTs 10.

FIG. 4 shows a second variant of the test apparatus 100 according to the present embodiment together with the DUTs 10.

FIG. 5 shows a third variant of the test apparatus 100 according to the present embodiment together with the DUT 10.

FIG. 6 shows one example of the hardware configuration of a computer 1900 that functions as a server apparatus 20 according to the present embodiment.

### DESCRIPTION OF EXEMPLARY EMBODIMENTS

The embodiments do not limit the invention according to the claims, and all the combinations of the features described in the embodiments are not necessarily essential to means provided by aspects of the invention.

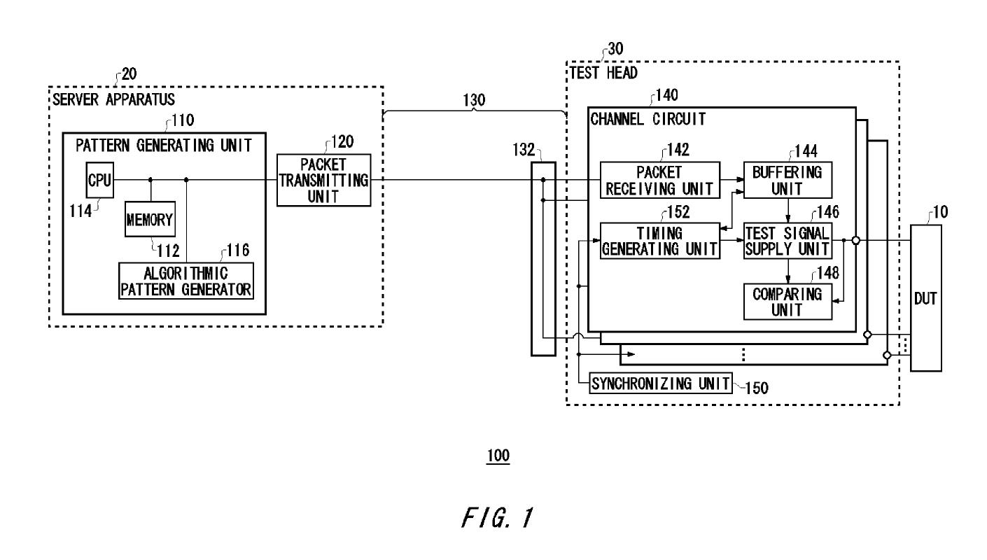

FIG. 1 shows a configuration example of a test apparatus 100 according to the present embodiment together with a DUT 10. The test apparatus 100 tests a device under test. The test apparatus 100 allows reduction of the number of pattern generators by providing a pattern generator that generates test patterns at a location that is different from a location of a test head connected to the device under test. In FIG. 1, the device under test is denoted with “DUT 10”. The DUT 10 is a device such as, for example, an analog circuit, a digital circuit, a memory and/or a system-on-a-chip (SOC).

The test apparatus 100 inputs, to the DUT 10, a test signal based on a test pattern for testing the DUT 10, and judges the quality of the DUT 10 based on an output signal output by the DUT 10 in response to the test signal. The test apparatus 100 comprises a server apparatus 20, a packet transferring unit 130 and a test head 30.

The server apparatus 20 generates a test pattern to be used by the test apparatus 100, and transfers, via the packet transferring unit 130, the test pattern to the test head 30 connected to the DUT 10. The server apparatus 20 may be any of an EWS (engineering work station), a workstation, a personal computer or the like, or a combination thereof. The server apparatus 20 has a pattern generating unit 110 and a packet transmitting unit 120.

The pattern generating unit 110 generates a test pattern to be supplied to the DUT 10. The pattern generating unit 110 may generate a test pattern during a test of the DUT 10 being conducted by the test apparatus 100. Instead of this or in addition to this, the pattern generating unit 110 may generate a test pattern before a test of the DUT 10 to be conducted by the test apparatus 100. The pattern generating unit 110 generates a test pattern based on operation of software or hardware. FIG. 1 is for explaining an example in which the pattern generating unit 110 generates test patterns based on operation of software and hardware, respectively. The pattern generating unit 110 includes a memory 112, a CPU 114 and an algorithmic pattern generator 116.

The memory 112 stores therein a test program for testing the DUT 10. Instead of this or in addition to this, the memory 112 may store therein a test pattern to be supplied to the DUT 10. In this case, the memory 112 may store therein a test pattern previously generated outside or inside the server apparatus 20. Also, the memory 112 may memorize respective ones of intermediate data, calculation results, parameters or the like generated (or utilized) in a course of pattern generation by the pattern generating unit 110. Also, in response to a request from each unit within the server apparatus 20, the memory 112 may supply memorized data or the like to a requestor.

The CPU 114 executes a test program to generate a test pattern. In this case, the CPU 114 may read out and execute the test program stored in the memory 112. Instead of this or in addition to this, the CPU 114 may instruct transmission of a test pattern stored in the memory 112. Instead of this or in addition to this, the CPU 114 may instruct the algorithmic pattern generator 116 to generate a test pattern.

The algorithmic pattern generator 116 generates a test pattern by hardware in which a predetermined algorithm is implemented. The algorithmic pattern generator 116 may include a FPGA and/or an ASIC, or the like.

As described above, the pattern generating unit 110 according to the present embodiment supplies the packet transmitting unit 120 with at least one of a test pattern generated by execution of software by the CPU 114, a test pattern stored in the memory 112, and a test pattern generated by the algorithmic pattern generator 116. The pattern generating unit 110 may have one or more functions among three pattern generation functions of: execution by software; storage by the memory 112; and generation by hardware, and generate a pattern.

The packet transmitting unit 120 packetizes and transmits a test pattern to be supplied to the DUT 10 during a test of the DUT 10. The packet transmitting unit 120 packetizes and transmits a test pattern received from the pattern generating unit 110. Here, the packet transmitting unit 120 packetizes and transmits, during a test of the DUT 10, for example a test pattern generated before the test of the DUT. Instead of this or in addition to this, the packet transmitting unit 120 may packetize and transmit, during a test of the DUT 10, a test pattern generated during the test of the DUT.

The packet transmitting unit 120 may packetize and transmit a test pattern portion by portion. The packet transmitting unit 120 in one example packetizes, into a predetermined data size, a portion of a test pattern, and header information including information about a transmission destination of the portion of the test pattern or the like. When packetizing, into a single packet, portions of a plurality of test patterns to be transmitted to a plurality of transmission destinations, the packet transmitting unit 120 may packetize, into a predetermined data size, information about the plurality of transmission destinations, and header information including information in which locations of test patterns to be transmitted within the packet, and the transmission destinations are associated with each other.

Also, the packet transmitting unit 120 performs DMA transfer of, for example, a test pattern generated by the pattern generating unit 110. The packet transmitting unit 120 in one example transmits, by DMA transfer and to the packet transferring unit 130, a test pattern stored in the memory 112. Also, the packet transmitting unit 120 may transmit, by DMA transfer and the to the packet transferring unit 130, a test pattern generated by execution of software by the CPU 114 and/or a test pattern generated by the algorithmic pattern generator 116. The packet transmitting unit 120 transfers a test pattern to the test head 30 via the packet transferring unit 130.

The packet transferring unit 130 transfers, to the test head 30, a packet transmitted by the packet transmitting unit 120. The packet transferring unit 130 may transfer the packet by using a standardized scheme. The packet transferring unit 130 in one example may transfer the packet by using the Ethernet (registered trademark) standard. In this case, the packet transferring unit 130 may be a portion of a network or an entire network. Also, the packet transferring unit 130 may be connected to another network or the like.

Also, the packet transferring unit 130 may transfer the packet through a P2P (peer-to-peer) connection that directly connects between devices.

The packet transferring unit 130 may have branching, distributing, switching or other functions, and transfer a packet. FIG. 1 shows an example in which the packet transferring unit 130 has a function of causing the packet to branch. In this case, the packet transferring unit 130 has a brancher 132. The brancher 132 causes a packet received from the packet transmitting unit 120 to branch. The brancher 132 in one example refers to header information including a transmission destination of the packet or the like to cause data included in the packet to branch to a corresponding transmission destination. The brancher 132 causes the packet to branch to a corresponding transmission destination inside the test head 30.

The test head 30 is connected to one or more DUTs 10, and tests the DUTs 10 based on transferred test patterns. FIG. 1 shows an example in which the test head 30 is connected to a single DUT 10, and tests the DUT 10. The test head 30 has a channel circuit 140 and a synchronizing unit 150.

The channel circuit 140 is provided corresponding to at least one testing terminal connected to the DUT 10, and gives and receives a test signal based on a transferred test pattern and a response signal according to the test signal. Here, one or more of the testing terminals may be provided to the channel circuit 140, corresponding to one or more input/output terminals provided to the DUT 10. That is, a plurality of the channel circuits 140 may be provided, each of which corresponding to one of one or more input/output terminals of the DUT 10. FIG. 1 shows an example in which a plurality of the channel circuits 140 is provided, each of which corresponding to one of the input/output terminals of the DUT 10. Such a plurality of channel circuits 140 provided corresponding to a single DUT is treated as a channel group circuit. Each channel group circuit (a plurality of channel circuits 140) includes a packet receiving unit 142, a buffering unit 144, a test signal supply unit 146, a comparing unit 148 and a timing generating unit 152.

The packet receiving unit 142 receives a test pattern transferred via the packet transferring unit 130. The packet receiving unit 142 in one example supplies the buffering unit 144 with data of a received packet except for header information. That is, the packet receiving unit 142 supplies the buffering unit 144 with information about the received test pattern.

The buffering unit 144 buffers the test pattern received by the packet receiving unit 142. The buffering unit 144 may buffer one or more packets, respectively, received by the packet receiving unit 142, and accumulate the test pattern portion by portion. The buffering unit 144 supplies the test signal supply unit 146 with a portion of the buffered and accumulated test patterns. The buffering unit 144 may include a FIFO circuit, and supply the test signal supply unit 146 with data that has been buffered temporally earlier, before data that has been buffered temporally later is supplied.

The test signal supply unit 146 supplies the DUT 10 with a test signal according to a test pattern acquired from the buffering unit 144. The test signal supply unit 146 may have a driver circuit, and supply the DUT 10 with a test signal having a voltage within a predetermined signal voltage range via the driver circuit. Also, the test signal supply unit 146 may generate an expected value of a response signal output by the DUT 10 in response to the test signal. In this case, the test signal supply unit 146 supplies the generated expected value to the comparing unit 148.

The comparing unit 148 receives a response signal output by the DUT 10 in response to a test signal. The comparing unit 148 may include a comparator circuit, and in this case, may compare the response signal of the DUT 10 with a threshold by the comparator circuit, and acquire a data value of the response signal. The comparing unit 148 may compare the data value included in the response signal of the DUT 10 with the expected value generated by the test signal supply unit 146, and judge the quality of the DUT 10 based on the comparison result.

The timing generating unit 152 generates timing at which a test pattern is supplied to the DUT 10. The timing generating unit 152 in one example causes a timing signal, indicating timing at which a test pattern is supplied, to be generated based on the amount of test patterns buffered and accumulated by the buffering unit 144. That is, the timing generating unit 152 generates a timing signal indicating timing that is different from and independent of timing at which the server apparatus 20 transfers a packet to the test head 30. Then, the timing generating unit 152 supplies the timing signal to the test signal supply unit 146.

Thereby, at timing generated by the timing generating unit 152, the test signal supply unit 146 supplies the DUT 10 with a test signal according to a test pattern buffered in the buffering unit 144. The timing generating unit 152 may supply the comparing unit 148 with a timing signal indicating timing at which a response signal is received, and/or a comparison timing signal indicating timing at which comparison with an expected value is performed, or other signals. In this manner, the timing generating unit 152 may have a timing control function for the channel circuit 140.

The synchronizing unit 150 synchronizes a plurality of channel circuits 140 (that is, a channel group circuit). That is, the synchronizing unit 150 performs synchronization control on transmission/reception timing of a plurality of test signals and response signals given to and received from input/output terminals provided to a single DUT 10. The synchronizing unit 150 may perform synchronization control by generating a synchronization timing signal, and supplying the synchronization timing signal to the timing generating unit 152 that each of the plurality of channel circuits 140 has. When a DUT 10 that can operate with no problems without synchronization of transmission/reception timing of test signals and response signals among different input/output terminals is used, the synchronizing unit 150 may not be present.

In the test apparatus 100 according to the present embodiment described above, the server apparatus 20 that is different from the test head 30 is provided with the pattern generating unit 110. The pattern generating unit 110 generates test patterns to be transmitted corresponding to each of a plurality of input/output terminals of the DUT 10, and performs packet transmission such that the test patterns are transferred to each of the channel circuits 140 corresponding to each of the plurality of input/output terminals. Thereby, the test apparatus 100 can test a DUT 10 without being provided with a pattern generating unit 110 for every one of channel circuits corresponding to an input/output terminal of the DUT 10, but for example by using a single pattern generating unit corresponding to the single DUT 10. Operation of such a test apparatus 100 is explained next.

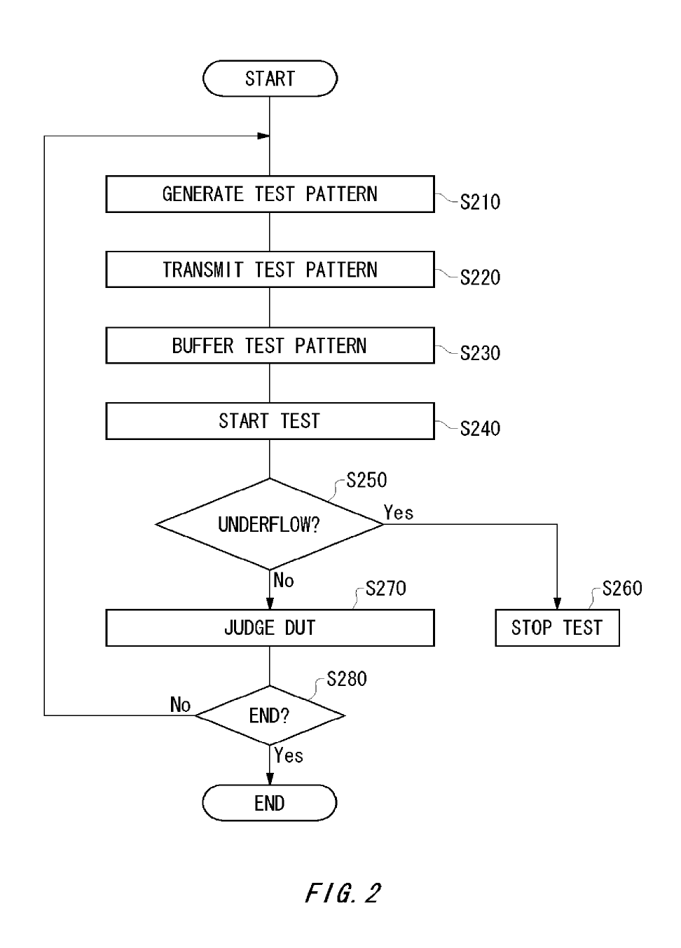

FIG. 2 shows one example of an operation flow of the test apparatus 100 according to the present embodiment. First, the pattern generating unit 110 generates a test pattern before starting a test (S210). The pattern generating unit 110 may select a means for generation according to a test pattern to be used. If the pattern generating unit 110 can generate a pattern by a simple algorithm, a simple program or the like, the CPU 114 may read out a corresponding program from the memory 112, and a test pattern may be generated by the CPU 114 executing the program.

Also, when a test pattern is generated by a complicated algorithm or the like, the pattern generating unit 110 may cause the algorithmic pattern generator 116 to generate the test pattern. Instead of this, the pattern generating unit 110 may supply the packet transmitting unit 120 with a test pattern having been generated inside or outside previously and memorized in the memory 112. Thereby, the pattern generating unit 110 can mitigate the load on the CPU 114. Also, the pattern generating unit 110 may perform DMA transfer of a generated test pattern, thereby mitigating the load on the CPU 114 and enabling high speed transfer of a large amount of test patterns.

The pattern generating unit 110 causes generated test patterns to be transferred sequentially. When there are not instructions to stop a test or other instructions, the pattern generating unit 110 may continue transfer of test patterns until generation of test patterns is ended, irrespective of operation of the test head 30.

Next, the packet transmitting unit 120 transmits a test pattern having been generated by the pattern generating unit 110 before the test of the DUT 10 (S220). The packet transmitting unit 120 transmits the test pattern to a corresponding channel circuit 140 of the test head 30 via the packet transferring unit 130. The buffering unit 144 that each of the channel circuit 140 has buffers the received test pattern (S230).

Upon the amount of test patterns buffered and accumulated by the buffering unit 144 exceeding a predetermined threshold, the timing generating unit 152 generates timing at which test patterns are supplied and supplies the timing to the test signal supply unit 146. Thereby, the test signal supply unit 146 starts the test of the DUT 10 (S240).

The timing generating unit 152 may determine the threshold of the accumulated amount in accordance with the transfer amount of the packet transferring unit 130, the buffer capacity of the buffering unit, the test speed of the test signal supply unit 146 and the comparing unit 148 or the like. Also, when the synchronizing unit 150 synchronizes a channel group circuit, the timing generating unit 152 may generate timing at which test patterns are supplied upon the accumulated amount of the buffering unit 144 exceeding a predetermined threshold under the condition that a synchronization signal has been received from the synchronizing unit 150.

The test signal supply unit 146 supplies test signals according to test patterns sequentially to the DUT 10. The test signal supply unit 146 continues supplying test signals until all of the test patterns buffered in the buffering unit 144 are supplied to the DUT 10. Also, the test signal supply unit 146 may insert a wait-cycle to test signals to be supplied to the DUT 10 when test patterns acquired from the buffering unit 144 include a wait-permission code that permits insertion of a wait-cycle, and additionally a remaining amount of test patterns buffered in the buffering unit 144 is equal to or less than a criterion.

Thereby, the test signal supply unit 146 can perform control of inserting a wait cycle in supplying test signals. The test signal supply unit 146 may determine a criterion for the remaining amount of test patterns of the buffering unit 144 so as not to cause overflow of test patterns accumulated in the buffering unit 144 during an inserted wait cycle, and preserve a free space in the buffering unit 144.

Also, the test signal supply unit 146 may cause a test pattern acquired from the buffering unit 144 to branch into a test pattern of a branch destination which has already been buffered when the test pattern includes a branch instruction within a range which is smaller than a size of the buffering unit 144. Thereby, the test signal supply unit 146 can perform branch control on test patterns in supplying test signals. When the test apparatus 100 executes a branch instruction within a range that is equal to or larger than the size of the buffering unit 144, the test apparatus 100 may execute the branch instruction at the packet transmitting step of the packet transmitting unit 120.

Also, the buffering unit 144 may hold buffered test patterns after usage, the number of the test patterns corresponding to a predetermined number of cycles. In this case, when a test pattern acquired from the buffering unit 144 includes a forward branch instruction, the test signal supply unit 146 causes the test pattern to branch into a used test pattern held in the buffering unit 144. In this manner, the test signal supply unit 146 according to the present embodiment can execute a branch instruction by using a test pattern buffered in the buffering unit 144. Thereby, the load on the packet transmitting unit 120 side can be mitigated, and stable packet transmission can be performed.

When test patterns buffered in the buffering unit 144 became insufficient while supply of test signals to the DUT 10 is continued, the test signal supply unit 146 determines that underflow has occurred to the buffering unit 144 (S250: Yes). In this case, the test signal supply unit 146 determines that the test of the DUT 10 has failed, and stops or suspends the test (S260). The test signal supply unit 146 may instruct the server apparatus 20 to stop the test, and the server apparatus 20 may stop test operation in response to the instruction and notify a user or the like of the test failure.

Also, when the test signal supply unit 146 has ended supply of test signals without occurrence of insufficiency of test patterns in the buffering unit 144 (S250: No), the comparing unit 148 receives a response signal output by the DUT 10 in response to test signals. The comparing unit 148 compares a data value included in the response signal of the DUT 10 with an expected value generated by the test signal supply unit 146, and judges the quality of the DUT 10 (S270).

When continuing with testing, the test apparatus 100 causes the pattern generating unit 110 to generate test patterns according to a next test (S280: No). The test apparatus 100 may repeat the operation of S210 to S270 until tests to be performed end. When tests to be performed end, the test apparatus 100 ends testing (S280: Yes).

As described above, the test apparatus 100 according to the present embodiment can perform the test pattern generation and transmission operation of the server apparatus 20 and the test operation of the test head 30 separately from and independently of each other as long as the buffering operation of the buffering unit 144 does not fail. Thereby, because the server apparatus 20, which is separate from and independent of the test head 30, can generate test patterns, the pattern generating unit 110 of the test head 30 can be omitted.

Also, because the packet transferring unit 130 can have branching, distributing, switching and other functions for test patterns generated by the server apparatus 20 and transfer them, the number of the pattern generating units 110 to be provided to the test apparatus 100 can be reduced. Also, because the pattern generating unit 110 is configured by using a general purpose device like the server apparatus 20, the labor of designing a dedicated device can be reduced. Also, because the pattern generating unit 110 can perform the test pattern generating operation partially or entirely by software, the operation can be performed easily without labor and costs even if changes have occurred to a pattern control instruction which is a portion of a pattern.

Also, because the number of the pattern generating units 110 to be provided to the test apparatus 100 can be reduced, even if changes have occurred to the hardware of the pattern generating units 110, such changes can be made collectively. In this manner, because the test apparatus 100 according to the present embodiment can reduce the number of the pattern generators to be provided to the test apparatus 100, and additionally perform the test pattern generating operation partially or entirely by software, it can reduce test costs.

The test apparatus 100 according to the present embodiment described above has been explained by referring to an example in which a single DUT 10 is tested. In addition to this, the test apparatus 100 may test a plurality of DUTs 10. In this case, in the test apparatus 100, a single channel group circuit may test a plurality of DUTs 10, or instead of this, each of the plurality of channel group circuits may test corresponding one of the plurality of DUTs 10. An example in which the test apparatus 100 has a plurality of channel group circuits corresponding to a plurality of DUTs 10 is explained next.

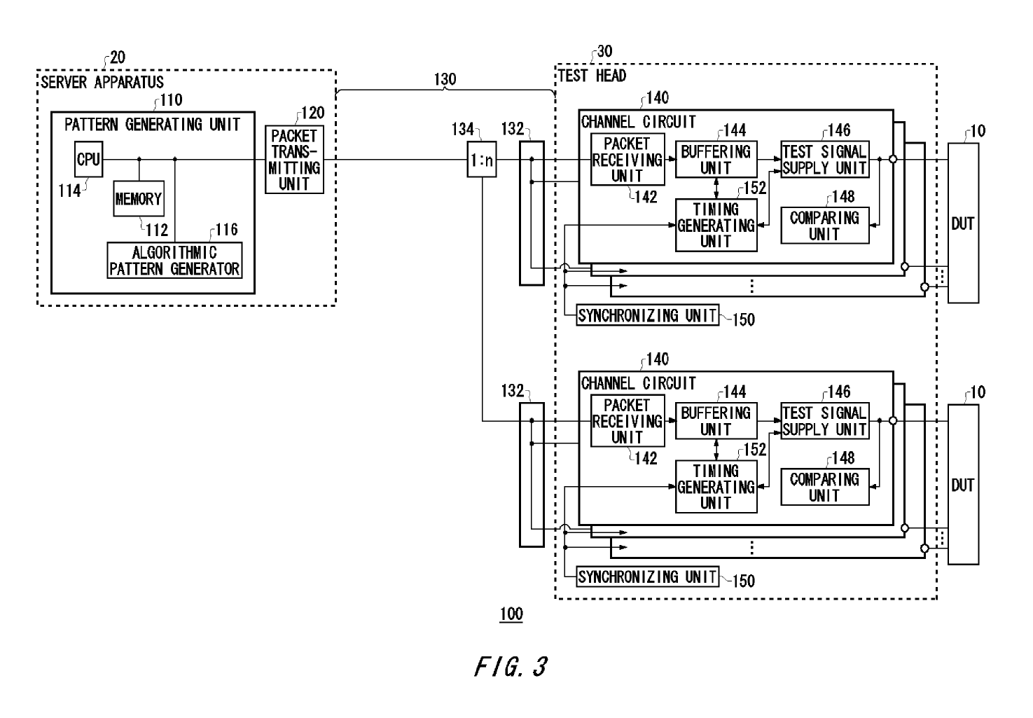

FIG. 3 shows a first variant of the test apparatus 100 according to the present embodiment together with the DUTs 10. FIG. 3 shows an example in which the test apparatus 100 having two channel group circuits is connected to the DUTs 10 at each of the channel group circuits, and tests each of the two DUTs 10. In the test apparatus 100 according to the first variant, units that perform operation that is substantially the same with the operation of units in the test apparatus 100 according to the present embodiment shown in FIG. 1 are denoted with the same symbols, and explanation thereof is omitted.

The test apparatus 100 comprises, at the test head 30, a plurality of channel group circuits which is provided corresponding to at least one testing terminal connected to the DUT 10, and each of which has the buffering unit 144 and the test signal supply unit 146. The test apparatus 100 may synchronize each channel group circuit separately, and in this case, the synchronizing unit 150 may be provided to each channel group circuit. FIG. 3 shows the test apparatus 100 comprising two channel group circuits corresponding to two DUTs 10, and two synchronizing units 150 that respectively control synchronization of the two channel group circuits.

FIG. 3 shows an example in which the same or substantially the same type of tests is performed on the two DUTs 10. That is, FIG. 3 shows an example in which the test apparatus 100 comprises a single server apparatus 20, and a test pattern generated by a single pattern generating unit 110 is supplied to respective ones of the two DUTs 10 via the two channel group circuits. The packet transmitting unit 120 may packetize and transmit a test pattern generated by the pattern generating unit 110 similar to the packet transmitting unit 120 of the test apparatus 100 shown in FIG. 1. The packet transmitting unit 120 may add, to a header of a packet, an instruction about a transmission destination channel group circuit.

The packet transferring unit 130 multicasts, to the two or more channel group circuits, a packet transmitted by the packet transmitting unit 120. In this case, the packet transferring unit 130 has a distributor 134 that distributes a packet received from the packet transmitting unit 120 to n, and multicasts the packet to n channel group circuits. FIG. 3 shows an example in which the distributor 134 distributes a received packet equally to two channel group circuits.

Also, the packet transferring unit 130 is provided with a plurality of branchers 132 corresponding to the plurality of channel group circuits, and the plurality of branchers 132 respectively cause a packet received from the packet transmitting unit 120 to branch. FIG. 3 shows an example in which two branchers 132 corresponding to the two channel group circuits cause a packet that each of them received from the distributor 134 to branch to a corresponding channel circuit 140. Thereby, the packet receiving units 142 of the plurality of channel group circuits can receive test patterns to be supplied to input/output terminals of the DUTs 10 connected to the channel circuits 140 to which the packet receiving units 142 are provided.

The buffering unit 144 of each of the plurality of channel group circuits buffers test patterns that are included in packets received by the packet receiving unit 142 and are associated with each of the plurality of channel group circuits. The timing generating units 152 of the plurality of channel group circuits generate timing at which test patterns are supplied based on the amount of test patterns buffered and accumulated by the corresponding buffering units 144. Because the test operation performed by the plurality of channel circuits 140 is substantially the same with the operation explained in FIG. 1 and FIG. 2, explanation thereof is omitted here.

Because the test apparatus 100 according to the first variant described above distributes, to a plurality of channel group circuits, a packet generated and transmitted by the pattern generating unit 110, the number of the pattern generating units 110 can be made smaller than the number of the channel group circuits. Because in this case, the load on the operation of the pattern generating unit 110 is substantially the same with the operation load of the pattern generating unit 110 that the test apparatus 100 explained in FIG. 1 and FIG. 2 has, tests of a plurality of DUTs 10 can be performed while supplying test patterns stably. Accordingly, the test apparatus 100 according to the first variant can reduce the number of pattern generators provided to the test apparatus 100 to reduce test costs.

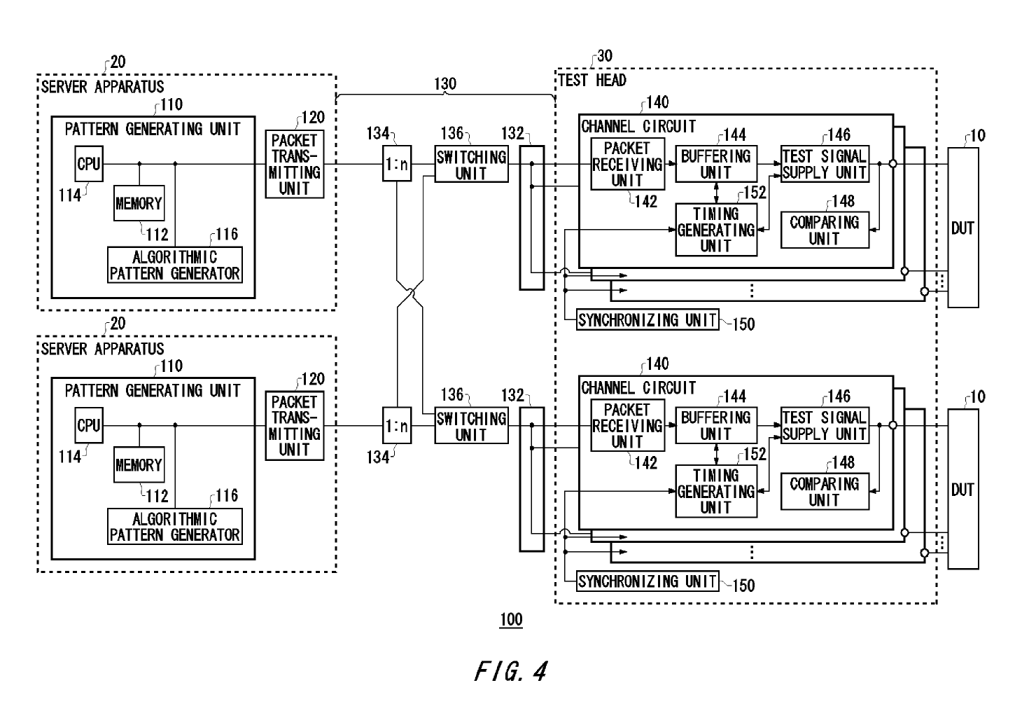

FIG. 4 shows a second variant of the test apparatus 100 according to the present embodiment together with the DUTs 10. FIG. 4 shows an example in which the test apparatus 100 having two channel group circuits is connected to DUTs 10 at each of the channel group circuits and performs tests that are different from each other on two DUTs 10. In the test apparatus 100 according to the second variant, units that perform operation that is substantially the same with the operation of units in the test apparatus 100 according to the present embodiment shown in FIG. 1 and FIG. 3 are denoted with the same symbols, and explanation thereof is omitted.

The test apparatus 100 comprises a plurality of channel group circuits at the test head 30. The test apparatus 100 may synchronize each channel group circuit separately, and in this case, the synchronizing unit 150 may be provided to each channel group circuit. Similar to FIG. 3, FIG. 4 shows the test apparatus 100 comprising two channel group circuits corresponding to two DUTs 10, and two synchronizing units 150 that respectively control synchronization of the two channel group circuits.

FIG. 4 shows an example in which different types of tests are performed on two DUTs 10. That is, FIG. 4 shows an example in which the test apparatus 100 comprises two server apparatuses 20 having pattern generating units 110, and different test patterns generated by the two pattern generating units 110 are respectively supplied to channel group circuits corresponding to the two DUTs 10. In this case, the packet transmitting units 120 may also be provided respectively to the server apparatuses 20, and packetize and respectively transmit test patterns generated by the pattern generating units 110. The packet transmitting unit 120 may add, to a header of a packet, an instruction about a transmission destination channel group circuit.

The packet transferring unit 130 has a switching unit 136 that switches to which one of the channel group circuits a packet transmitted by the packet transmitting unit 120 is transferred. FIG. 4 shows an example of two-input and one-output switching unit 136 that performs switching so that either one of packets transmitted by the two packet transmitting units 120 is to be transferred to a single channel group circuit connected to the output. The packet transferring unit 130 may have a plurality of switching units 136 corresponding to the number of transmission destination channel group circuits.

In this case, the packet transferring unit 130 may have n distributors 134 that distribute a packet received from the packet transmitting unit 120 to n, and each of the distributors 134 may multicast them to n channel group circuits via n switching units 136. FIG. 4 shows an example in which each of the two distributors 134 distributes a received packet substantially equally to two channel group circuits via the two switching units 136. Also, the packet transferring unit 130 is provided with a plurality of branchers 132 corresponding to a plurality of channel group circuits, and the plurality of branchers 132 respectively cause packets received from the packet transmitting units 120 to branch.

Thereby, the packet receiving units 142 of the plurality of channel group circuits can receive test patterns to be supplied to input/output terminals of the DUTs 10 connected to the channel circuits 140 provided with the packet receiving units 142. Here, the test apparatus 100 may supply different test patterns respectively from the plurality of server apparatuses 20, and the packet receiving units 142 can receive, from among the plurality of test patterns, test patterns to be supplied to the input/output terminals of the corresponding DUTs 10.

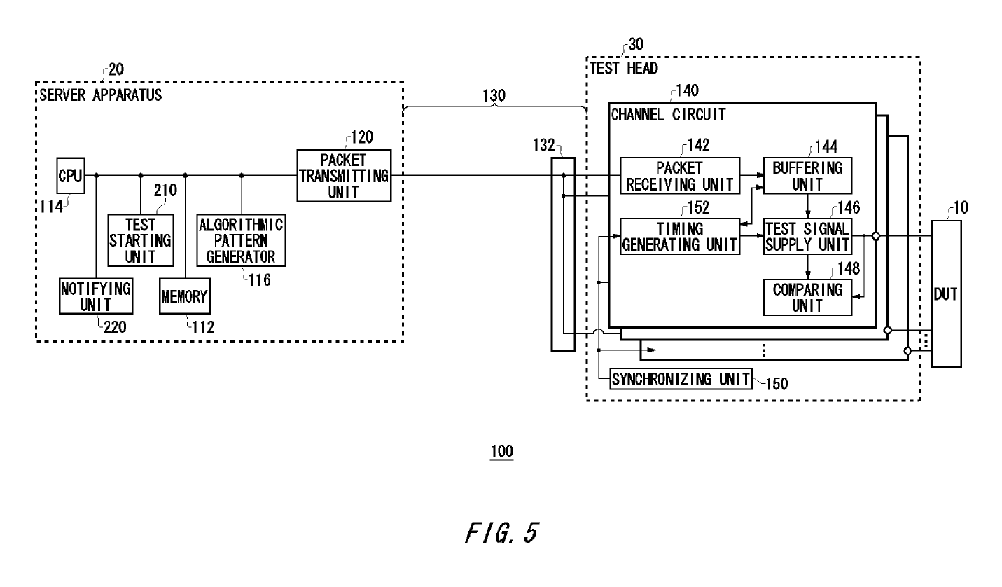

The test apparatus 100 according to the present embodiment described above was explained by referring to an example in which the timing generating units 152 generate timing at which test patterns are supplied to the DUTs 10, and tests of the DUTs 10 are started. Instead of this or in addition to this, in the test apparatus 100, the server apparatus 20 may generate timing at which test patterns are supplied to the DUT 10. Such a test apparatus 100 is explained by using FIG. 5.

FIG. 5 shows a third variant of the test apparatus 100 according to the present embodiment together with the DUT 10. FIG. 5 shows an example in which the test apparatus 100 having a single channel group circuit is connected to a single DUT 10, and a test of the DUT 10 is performed at timing generated by the server apparatus 20. In the test apparatus 100 according to the third variant, units that perform operation that is substantially the same with the operation of units in the test apparatus 100 according to the present embodiment shown in FIG. 1 are denoted with the same symbols, and explanation thereof is omitted.

In the test apparatus 100 according to the third variant, the state of the channel circuit 140 is notified from the test head 30 side to the server apparatus 20 via the packet transferring unit 130. In one example, information about the amount of test patterns buffered and accumulated by the buffering unit 144 is notified to the server apparatus 20. In this case, the buffering unit 144 may supply the information to the packet transmitting unit 120 via the packet receiving unit 142, and instead of this, the timing generating unit 152 may supply the information to the packet transmitting unit 120 via the packet receiving unit 142.

In the test apparatus 100 according to the third variant, the packet receiving unit 142 has a function of transmitting the information, and the packet transmitting unit 120 has a function of receiving the information. The packet transmitting unit 120 and the packet receiving unit 142 preferably have functions of transmitting and receiving packets. In the test apparatus 100 according to the third variant, the server apparatus 20 further has a test starting unit 210 and a notifying unit 220.

The test starting unit 210 starts a test of the DUT 10 upon a predetermined amount of test patterns having been buffered in the buffering unit 144. The test starting unit 210 may determine whether or not to start a test of the DUT 10 depending on a result of comparison between information about an accumulated amount in the buffering unit 144 notified from the test head 30 side and a predetermined amount. When starting a test of the DUT 10, the test starting unit 210 notifies the buffering unit 144 of the test start. In this case, the test starting unit 210 may supply a timing signal notifying the test start from the packet transmitting unit 120 via the packet transferring unit 130 and the packet receiving unit 142.

Thereby, the test head 30 can start a test of the DUT 10 at timing according to the buffered amount in the buffering unit 144. Also, the server apparatus 20 can grasp the buffered amount of test patterns supplied to the test head 30. That is, the server apparatus 20 can sense whether or not the test pattern buffering operation on the test head 30 side is normal.

The notifying unit 220 notifies test failure attributable to the test apparatus 100 upon underflow having occurred to the buffering unit 144 during the test of the DUT 10. That is, when abnormality of the test pattern buffering operation on the test head 30 side has been sensed, the notifying unit 220 notifies the test apparatus 100 user or the like of the abnormality. Also, the notifying unit 220 may display on a display of the server apparatus 20 or the like that the abnormality has been sensed. Thereby, the server apparatus 20 can sense and notify abnormality of the test pattern buffering operation on the test head 30 side. Also, the server apparatus 20 may stop or suspend the test depending on the abnormality sensing result.

As described above, the server apparatus 20 according to the present embodiment generates a test pattern and supplies it to the test head 30 at a location apart from the DUT 10. By using the supplied test patterns, the test head 30 tests the DUT 10 at timing independent of timing at which a test pattern is received from the server apparatus 20. Thereby, the channel circuit 140 provided to the test head 30 is no longer required to have a function of generating test patterns, and can operate as a test signal supply device provided to the test apparatus 100 that tests the DUT 10 in response to a received test pattern.

It has been explained that in the test apparatus 100 according to the present embodiment described above, the server apparatus 20 generates test patterns, and based on the generated test patterns, the test signal supply unit 146 supplies test signals to the DUT 10. Instead of this, the test apparatus 100 may function as an arbitrary waveform generating apparatus that supplies an analog waveform to the DUT 10.

In this case, the server apparatus 20 in one example generates a signal pattern with a signal waveform to be supplied to the DUT 10, and the test signal supply unit 146 supplies an analog signal to be supplied to the DUT 10. That is, the test signal supply unit 146 includes a DA converter, and converts a signal pattern generated by the server apparatus 20 into an analog signal, and supplies it to the DUT 10. In such a test apparatus 100 also, the test apparatus 100 can test the DUT 10 without providing the pattern generating unit 110 for each channel circuit corresponding to an input/output terminal of the DUT 10.

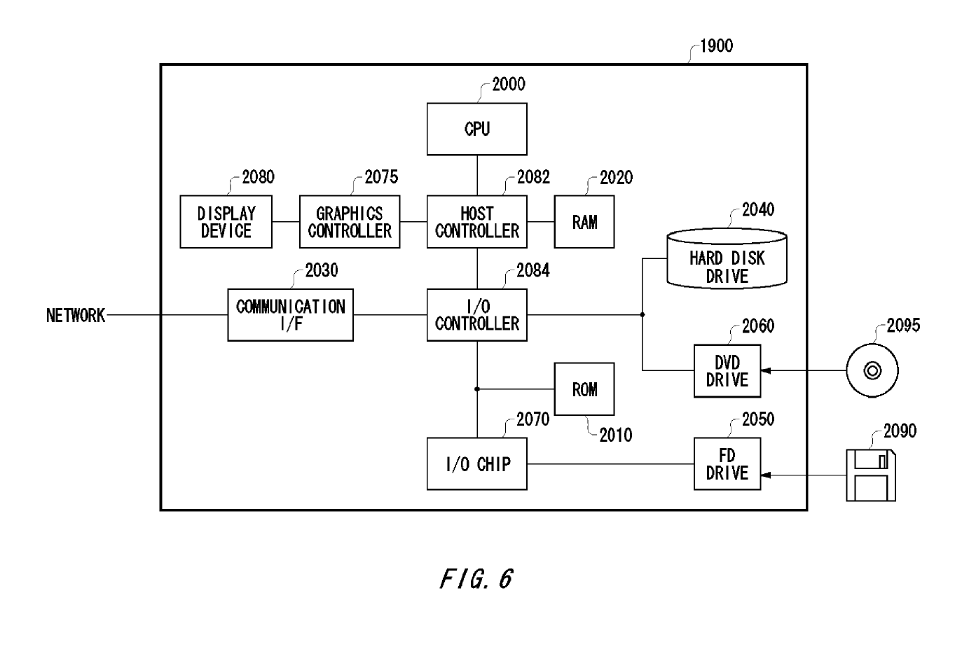

FIG. 6 shows one example of the hardware configuration of a computer 1900 that functions as the server apparatus 20 according to the present embodiment. The computer 1900 according to the present embodiment comprises: a CPU peripheral unit having a CPU 2000, a RAM 2020, a graphics controller 2075 and a display device 2080 that are interconnected by a host controller 2082; an input/output unit having a communication interface 2030, a hard disk drive 2040 and a DVD drive 2060 connected to the host controller 2082 by an input/output controller 2084; and a legacy input/output unit having a ROM 2010, a flexible disk drive 2050 and an input/output chip 2070 connected to the input/output controller 2084.

The host controller 2082 connects the RAM 2020, and the CPU 2000 and graphics controller 2075 that access the RAM 2020 at high transfer rates. The CPU 2000 operates based on a program stored on the ROM 2010 and the RAM 2020, and controls each unit. The graphics controller 2075 acquires image data to be generated on a frame buffer provided within the RAM 2020 by the CPU 2000 or the like, and displays the image data on the display device 2080. Instead of this, the graphics controller 2075 may include therein a frame buffer that stores image data generated by the CPU 2000 or the like.

The input/output controller 2084 connects the host controller 2082, and the communication interface 2030, hard disk drive 2040 and DVD drive 2060 that are relatively high speed input/output devices. The communication interface 2030 communicates with other devices via a network. The hard disk drive 2040 stores therein a program and data to be used by the CPU 2000 within the computer 1900. The DVD drive 2060 reads out a program or data from the DVD-ROM 2095, and provides them to the hard disk drive 2040 via the RAM 2020.

Also, the ROM 2010, and relatively low speed input/output devices of the flexible disk drive 2050 and input/output chip 2070 are connected to the input/output controller 2084. The ROM 2010 stores therein a boot-program that the computer 1900 executes at the time of start-up and/or a program that is dependent on hardware of the computer 1900, or the like. The flexible disk drive 2050 reads out a program or data from the flexible disk 2090, and provides them to the hard disk drive 2040 via the RAM 2020. The input/output chip 2070 connects the flexible disk drive 2050 to the input/output controller 2084, and also connects various types of input/output devices to the input/output controller 2084 via, for example, a parallel port, a serial port, a keyboard port, a mouse port or the like.

A program to be provided to the hard disk drive 2040 via the RAM 2020 is provided by a user by being stored in a recording medium such as the flexible disk 2090, the DVD-ROM 2095, an IC card or the like. The program is read out from the recording medium, installed in the hard disk drive 2040 within the computer 1900 via the RAM 2020, and executed in the CPU 2000.

The program is installed in the computer 1900, and causes the computer 1900 to function as the pattern generating unit 110, the memory 112, the CPU 114, the algorithmic pattern generator 116, the packet transmitting unit 120, the test starting unit 210 and the notifying unit 220.

Information processing described in the program is read by the computer 1900 to function as the pattern generating unit 110, the memory 112, the CPU 114, the algorithmic pattern generator 116, the packet transmitting unit 120, the test starting unit 210 and the notifying unit 220 which are specific means that are realized by cooperation between software and the various types of hardware resources described above. By realizing, with these specific means, operation or processing on information according to purposes of usage of the computer 1900 in the present embodiment, the server apparatus 20 that has characteristics according to the purposes of usage is constructed.

In one example, when communication is performed between the computer 1900 and an external device or the like, the CPU 2000 executes a communication program loaded onto the RAM 2020, and based on the processing contents described in the communication program, instructs the communication interface 2030 to perform a communication process. Under control of the CPU 2000, the communication interface 2030 reads out transmitted data memorized in a transmission buffer region or the like provided on a storage such as the RAM 2020, the hard disk drive 2040, the flexible disk 2090 or the DVD-ROM 2095 to transmit the data to a network, or writes received data received from a network into a reception buffer region or the like provided on a storage. In this manner, the communication interface 2030 may forward transmitted/received data between storages by the DMA (direct memory access) scheme, or instead of this, the CPU 2000 may forward transmitted/received data by reading out data from a transfer source storage or communication interface 2030, and writing the data into a transfer destination communication interface 2030 or storage.

Also, the CPU 2000 causes all or necessary portions of files, databases or the like stored in an external storage such as the hard disk drive 2040, the DVD drive 2060 (DVD-ROM 2095) or the flexible disk drive 2050 (flexible disk 2090) to be read into the RAM 2020 by the DMA transfer or other schemes, and performs various types of processing on the data on the RAM 2020. The CPU 2000 writes the data on which processing has been performed back into an external storage by the DMA transfer or other schemes. Because in such processing, the RAM 2020 can be regarded as holding contents of the external storage temporarily, the RAM 2020 and the external storage or the like are collectively called a memory, a memory unit, a storage or the like in the present embodiment. Various types of information such as various types of programs, data, tables, databases or the like in the present embodiment are stored in such a storage, and are subjected to information processing. The CPU 2000 can also hold a portion of the RAM 2020 on a cache memory, and read out from and write in the cache memory. Because in such an embodiment also, the cache memory plays a role of a portion of functions of the RAM 2020, in the present embodiment, the cache memory is also regarded as being included in the RAM 2020, a memory and/or a storage unless otherwise they are distinguished from each other.

Also, the CPU 2000 performs, on data read out from the RAM 2020, various types of processing including various types of operation, information processing, conditional judgment, information search/replacement or the like described in the present embodiment that are specified in an instruction sequence of a program, and writes the data back into the RAM 2020. For example, when performing conditional judgment, the CPU 2000 compares various types of variables shown in the present embodiment to judge whether they meet conditions such as being larger than, smaller than, equal to or larger than, equal to or smaller than other variables or constants, and when a condition is met (or when it is not met) branches to a different instruction sequence or calls up a subroutine.

Also, the CPU 2000 can search information stored in files, databases or the like in a storage. For example, when a plurality of entries in which attribute values of a second attribute are respectively associated with attribute values of a first attribute are stored in a storage, the CPU 2000 searches, from among the plurality of entries stored in the storage, an entry whose attribute value of the first attribute matches a specified condition, and reads out the attribute value of the second attribute stored in the entry, thereby obtaining the attribute value of the second attribute associated with the first attribute that meets a predetermined condition.

The programs or modules shown above may be stored in an external recording medium. The recording medium to be used may be, other than the flexible disk 2090 and the DVD-ROM 2095, an optical recording medium such as DVD, Blue-ray (registered trademark) or CD, a magneto-optical recording medium such as MO, a tape medium, a semiconductor memory such as IC card or the like. Also, a storage such as a hard disk or a RAM provided to a server system connected to a dedicated communication network or the Internet may be used as a recording medium, and a program may be provided to the computer 1900 via the network.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, the test apparatus comprising:
a packet transmitting unit that packetizes and transmits, during a test of the device under test, a test pattern to be supplied to the device under test;
a packet transferring unit that transfers a packet transmitted by the packet transmitting unit;
a packet receiving unit that receives the test pattern transferred via the packet transferring unit;
a buffering unit that buffers the test pattern received by the packet receiving unit; and
a test signal supply unit that supplies the device under test with a test signal according to the test pattern acquired from the buffering unit.

2. The test apparatus according to claim 1, further comprising a pattern generating unit that generates the test pattern to be supplied to the device under test.

3. The test apparatus according to claim 2, wherein the pattern generating unit generates the test pattern during the test of the device under test.

4. The test apparatus according to claim 2, wherein the pattern generating unit has:
a memory that stores therein a test program for testing the device under test; and
a CPU that executes the test program to generate the test pattern.

5. The test apparatus according to claim 2, wherein the pattern generating unit has an algorithmic pattern generator that generates the test pattern by hardware in which a predetermined algorithm is implemented.

6. The test apparatus according to claim 1, wherein during the test of the device under test, the packet transmitting unit packetizes and transmits the test pattern generated before the test of the device under test.

7. The test apparatus according to claim 1, comprising a memory that stores therein the test pattern to be supplied to the device under test, wherein
the packet transmitting unit transmits, by DMA transfer and to the packet transferring unit, the test pattern stored in the memory.

8. The test apparatus according to claim 1, further comprising a timing generating unit that generates timing at which the test pattern is supplied to the device under test, wherein
the test signal supply unit supplies, at the timing generated by the timing generating unit and to the device under test, the test signal according to the test pattern buffered in the buffering unit.

9. The test apparatus according to claim 1, comprising a plurality of channel group circuits which is provided corresponding to at least one testing terminal connected to the device under test, and each of which has the buffering unit and the test signal supply unit.

10. The test apparatus according to claim 9, wherein the buffering unit in each of the plurality of channel group circuits buffers the test pattern which is included in the packet received by the packet receiving unit and associated with each of the plurality of channel group circuits.

11. The test apparatus according to claim 9, wherein the packet transferring unit multicasts, to two or more channel group circuits, the packet transmitted by the packet transmitting unit.

12. The test apparatus according to claim 9, wherein the packet transferring unit has a switching unit that switches to which one of the channel group circuits the packet transmitted by the packet transmitting unit is transferred.

13. The test apparatus according to claim 1, wherein
the packet transmitting unit transmits the test pattern before the test of the device under test, and
the test apparatus further comprises a test starting unit that starts the test of the device under test upon a predetermined amount of the test pattern having been buffered in the buffering unit.

14. The test apparatus according to claim 1, further comprising a notifying unit that notifies test failure attributable to the test apparatus upon underflow having occurred to the buffering unit during the test of the device under test.

15. The test apparatus according to claim 1, wherein the test signal supply unit inserts a wait-cycle to the test signal supplied to the device under test when the test pattern acquired from the buffering unit includes a wait-permission code that permits insertion of a wait-cycle, and additionally a remaining amount of the test pattern buffered in the buffering unit is equal to or less than a criterion.

16. The test apparatus according to claim 1, wherein when the test pattern acquired from the buffering unit includes a branch instruction within a range which is smaller than a size of the buffering unit, the test signal supply unit causes the test pattern to branch into a test pattern of a branch destination having already been buffered

17. The test apparatus according to claim 16, wherein
the buffering unit holds the buffered test pattern after usage, the number of the test pattern corresponding to a predetermined number of cycles; and
when the test pattern acquired from the buffering unit includes a forward branch instruction, the test signal supply unit causes the test pattern to branch into a used test pattern held in the buffering unit.

18. A test signal supply apparatus provided in a test apparatus that tests a device under test, the test signal supply apparatus comprising:
a packet receiving unit that receives, from a packet transferring unit that transfers in a packet a test pattern to be supplied to the device under test, the test pattern during a test of the device under test;
a buffering unit that buffers the test pattern received by the packet receiving unit; and
a test signal supply unit that supplies the device under test with a test signal according to the test pattern acquired from the buffering unit.

19. A test method that tests a device under test, the test method comprising:
packetizing and transmitting, during a test of the device under test, a test pattern to be supplied to the device under test;
transferring the packet transmitted in the packetizing and transmitting;
receiving the test pattern transferred in the transferring;
buffering, in a buffering unit, the test pattern received in the receiving; and
supplying the device under test with a test signal according to the test pattern acquired from the buffering unit.

20. A computer readable recording medium having recorded therein a program that, upon being executed by a computer, generates the test pattern to be used by the test apparatus according to claim 1, wherein
the program causes the computer to function as:
a pattern generating unit that, during the test of the device under test, generates the test pattern to be supplied to the device under test; and
a packet transmitting unit that packetizes and transmits the generated test pattern.
